(19) United States
(12) Patent Application Publication
(10) Pub. No.: US 2026/0126568 A1
(43) Pub. Date: May 7, 2026

(54) LENS WITH MICRO-STRUCTURES

(71) Applicant: Industrial Technology Research Institute, Hsinchu (TW)

(72) Inventors: Chun-Ting Lin, New Taipei City (TW); Yi-Hsiang Huang, Changhua County (TW); Hung Tsou, Hsinchu County (TW)

(73) Assignee: Industrial Technology Research Institute, Hsinchu (TW)

(21) Appl. No.: 19/001,526

(22) Filed: Dec. 25, 2024

(30) Foreign Application Priority Data
Nov. 5, 2024 (TW) 113142256

(51) Int. Cl. G02B 3/08; H10H 20/855

(52) U.S. Cl. CPC G02B 3/08; H10H 20/855

(57) ABSTRACT

A lens with micro-structures include a lens body and a plurality of micro-structures. The lens body has a bottom surface and a curved surface. The micro-structures are disposed on the curved surface of the lens body. Each of the micro-structures has a circular outer edge. In view from atop of the lens body, center points of the circular outer edges of the micro-structures are located at a same position. The circular outer edges are arranged at equal intervals.

### CROSS-REFERENCE TO RELATED APPLICATION

This application claims the priority benefit of Taiwan application serial no. 113142256, filed on Nov. 5, 2024. The entirety of the above-mentioned patent application is hereby incorporated by reference herein.

### TECHNICAL FIELD

The disclosure relates to a lens with micro-structures.

### BACKGROUND

Displays have been widely used. As the demand for high brightness and high contrast of displays gradually grows, for display types that require backlight modules such as liquid crystal displays, the use of direct-lit backlight modules has gradually become the mainstream. In the direct-lit backlight modules of liquid crystal displays, most of the time, bare chip design is adopted for the light-emitting diode chips used therein, and diffuser sheets and prism sheets are usually placed above these array-arranged light-emitting diode chips. The diffuser sheets provide a light-homogenizing effect for the light emitted by the light-emitting diode chips, and the prism sheets provide a light-concentrating effect for the light emitted by the light-emitting diode chips. The combination of the diffuser sheets and the prism sheets often causes in the light to have maximum intensity in the normal direction of the liquid crystal display, so that this design will lead to overall illumination of the liquid crystal display to be uneven. Generally, it is necessary to shorten the arrangement interval between the light-emitting diode chips, and high-haze diffuser sheets are required to be used to address the aforementioned problem. However, when the arrangement interval between the light-emitting diode chips is decreased, the number of light-emitting diode chips used in the direct-lit backlight module will increase, and when the number of light-emitting diode chips used increases, the manufacturing costs of the direct-lit backlight module hike. Therefore, how to improve the overall illumination uniformity with a limited number of light-emitting diodes is a challenge that designers in this field need to face.

### SUMMARY

An embodiment of the disclosure provides a lens with micro-structures including a lens body and a plurality of micro-structures. The lens body has a bottom surface and a curved surface. The micro-structures are disposed on the curved surface of the lens body. Each of the micro-structures has a circular outer edge. In view from atop of the lens body, center points of the circular outer edges of the micro-structures are located at a same position. The circular outer edges are arranged at equal intervals.

Another embodiment of the disclosure further provides a lens with micro-structures including a lens body and a plurality of micro-structures. The lens body has a bottom surface, a top surface, and a curved surface, and the curved surface extends between the top surface and the bottom surface. The micro-structures are disposed on the curved surface of the lens body. Each of the micro-structures has a circular outer edge. In view from atop of the lens body, center points of the circular outer edges of the micro-structures are located at a same position. The circular outer edges are arranged at equal intervals.

Several exemplary embodiments accompanied with figures are described below to further describe the disclosure.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1 is a cross-sectional schematic view of a lens with micro-structures and a light-emitting diode chip according to a first embodiment of the disclosure.

FIG. 2 is a three-dimensional schematic view of the lens with micro-structures according to the first embodiment of the disclosure.

FIG. 3A and FIG. 3B are schematic charts of intensity distribution of light emitted by a light-emitting diode after passing through different lenses with micro-structures according to the first embodiment of the disclosure.

FIG. 4 is a cross-sectional schematic view of a lens with micro-structures and a light-emitting diode chip according to a second embodiment of the disclosure.

FIG. 5 is a three-dimensional schematic view of the lens with micro-structures according to the second embodiment of the disclosure.

FIG. 6A and FIG. 6B are schematic charts of intensity distribution of light emitted by a light-emitting diode after passing through different lenses with micro-structures according to the second embodiment of the disclosure.

FIG. 7A to FIG. 7D are cross-sectional schematic views of lenses with micro-structures according to different embodiments of this disclosure.

FIG. 8 is a cross-sectional schematic view of a lens with micro-structures and a light-emitting diode chip according to a third embodiment of the disclosure.

FIG. 9 is a three-dimensional schematic view of the lens with micro-structures according to the third embodiment of the disclosure.

FIG. 10 is a schematic chart of intensity distribution of light emitted by a light-emitting diode after passing through the lens with micro-structures according to the third embodiment of this disclosure.

FIG. 11 is a cross-sectional schematic view of a lens with micro-structures and a light-emitting diode chip according to a fourth embodiment of the disclosure.

FIG. 12 is a three-dimensional schematic view of the lens with micro-structures according to the fourth embodiment of the disclosure.

FIG. 13 is a schematic chart of intensity distribution of light emitted by a light-emitting diode after passing through the lens with micro-structures according to the fourth embodiment of this disclosure.

FIG. 14A to FIG. 14C are three-dimensional schematic views of lenses with micro-structures according to other embodiments of this disclosure.

### DETAILED DESCRIPTION OF DISCLOSURED EMBODIMENTS

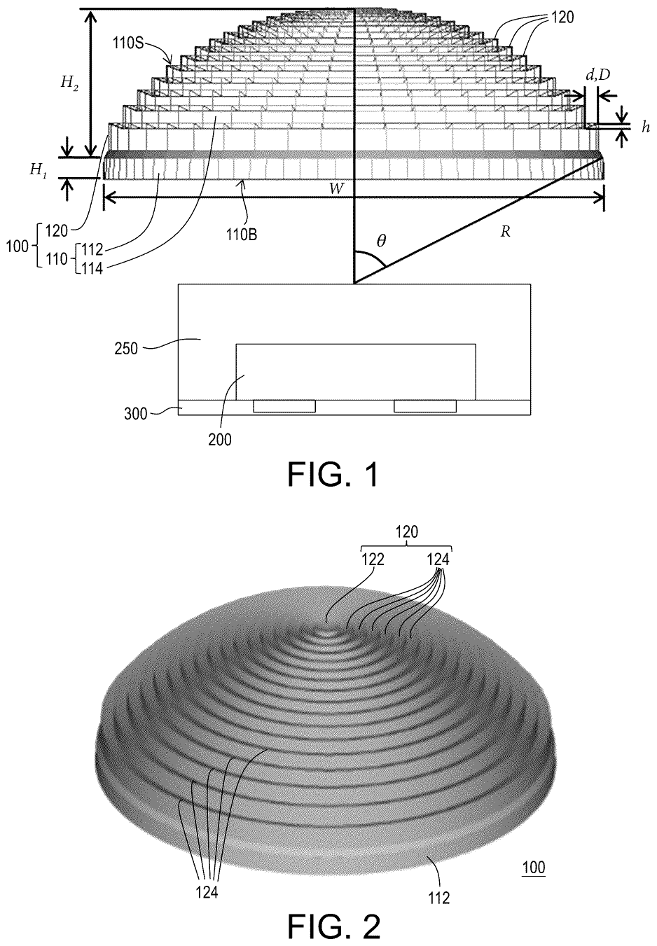

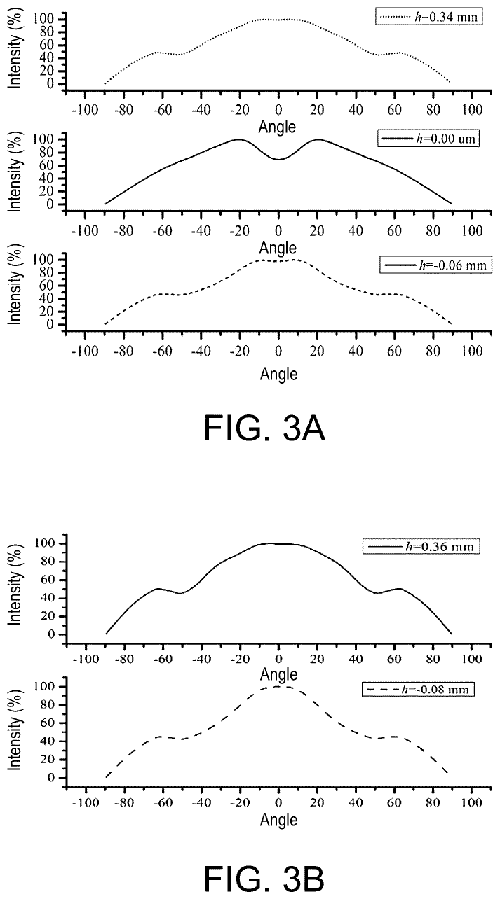

FIG. 1 is a cross-sectional schematic view of a lens with micro-structures and a light-emitting diode chip according to a first embodiment of the disclosure. FIG. 2 is a three-dimensional schematic view of the lens with micro-structures according to the first embodiment of the disclosure. FIG. 3A and FIG. 3B are schematic charts of intensity distribution of light emitted by a light-emitting diode after passing through different lenses with micro-structures according to the first embodiment of the disclosure.

With reference to FIG. 1 and FIG. 2, a lens with micro-structures 100 of this embodiment includes a lens body 110 and a plurality of micro-structures 120 located on the lens body 110. The lens body 100 has a bottom surface 110B and a curved surface 110S. The micro-structures 120 are disposed on the curved surface 110S of the lens body 110, and each of the micro-structures 120 has a circular outer edge. In view from atop of the lens body 110, center points of the circular outer edges of the micro-structures 120 are located at a same position. Further, the circular outer edges are arranged at equal intervals D. Herein, the arrangement interval D may be defined as a lateral distance between the circular outer edge of each micro-structure 120 and the circular outer edge of the adjacent micro-structure 120 (e.g., the adjacent micro-structure 120 in an inner ring or in an outer ring). In this embodiment, the arrangement interval D between the micro-structures 120 may range from 0.005 mm to 0.5 mm, for example. For instance, the arrangement interval D between the micro-structures 120 is 0.1 mm.

A light-emitting diode chip 200 is arranged on a circuit board 300, is electrically connected to the circuit board 300, and may be encapsulated by an encapsulation colloid 250 arranged on the circuit board 300. In some embodiments, the encapsulation colloid 250 may be an optical colloid, may be used to protect the light-emitting diode chip 200, and is conducive to transmitting the light emitted by the light-emitting diode chip 200. The light-emitting diode chip 200, the encapsulation colloid 250, and the circuit board 300 are arranged below the lens with micro-structures 100, and the light-emitting diode chip 200 and the encapsulation colloid 250 are located between the lens with micro-structures 100 and the circuit board 300. For instance, both a length and a width of the light-emitting diode chip 200 are 0.508 mm, a thickness of the light-emitting diode chip 200 is 0.15 mm, while a length and a width of the encapsulation colloid 250 are both greater than the length and width of the light-emitting diode chip 200, and a thickness of the encapsulation colloid 250 is greater than the thickness of the light-emitting diode chip 200. In this embodiment, the circuit board 300 may include a rigid printed circuit board, a flexible printed circuit board, or other types of circuit substrates. As shown in FIG. 1, the lens with micro-structures 100 is arranged above the light-emitting diode chip 200. The light-emitting diode chip 200 is adapted to emit light. A position of the lens with micro-structures 100 is arranged to allow the lens with micro-structures 100 to cover most of the light emitted by the light-emitting diode chip 200. The lens with micro-structures 100 may be arranged above a single light-emitting diode chip 200 or plural light-emitting diode chips 200. In this embodiment, a half-arc angle of the lens with micro-structures 100 may be equivalent to a beam divergence half-angle of the light-emitting diode chip 200, and both the half-arc angle of the lens with micro-structures 100 and the beam divergence half-angle of the light-emitting diode chip 200 are θ, where θ ranges from 20 degrees to 80 degrees. For instance, the half-arc angle of the lens with micro-structures 100 and the beam divergence half-angle θ of the light-emitting diode chip 200 are approximately 60 degrees. A minimum distance between the light-emitting diode chip 200 and the lens with micro-structures 100 may be determined according to the overall optical design.

In some embodiments, the number of light-emitting diode chips 200 may be multiple, and the multiple light-emitting diode chips 200 are arranged in an array on the circuit board 300. The number of lenses with micro-structures 100 may also be multiple, and the lenses with micro-structures 100 are arranged in an array above the corresponding light-emitting diode chips 200. The aforementioned array-arranged light-emitting diode chips 200 and array-arranged lenses with micro-structures 100 may form a direct-lit backlight module that provides a planar light source. Further, according to the overall optical design of the direct-lit backlight module, a appropriate number of diffuser sheet and/or prism sheets may be selectively placed between the array-arranged light-emitting diode chips 200 and the array-arranged lenses with micro-structures 100, so that the direct-lit backlight module is able to provide a planar light source with good uniformity.

As shown in FIG. 1, to further enhance the uniformity of light source distribution, the lens body 110 of this embodiment includes a base portion 112 and a curved portion 114 located on the base portion 112. Herein, the base portion 112 and the curved portion 114 may be integrally formed, for example, the base portion 112 and the curved portion 114 may be made of a same optical material. In other embodiments, the base portion 112 and the curved portion 114 may be made of different optical materials (e.g., materials with different refractive indices). As can be seen from FIG. 1 and FIG. 2, a bottom surface of the base portion 112 is the bottom surface 110B of the lens body 110, and an upper surface of the curved portion 114 is the curved surface 110S of the lens body 110. The base portion 112 may be a circular cylinder and has a thickness H1. The bottom surface 110B of the lens body 110 may be a circular bottom surface with a diameter W. The curved surface 110S of the curved portion 114 has a radius of curvature R and has a maximum height H2. The thickness H1 of the base portion 112 is between 0.05 mm and 5 mm, the diameter W of the bottom surface 110B is between 0.5 mm and 5 mm, the radius of curvature R of the curved surface 110S is between 0.1 mm and 10 mm, and the maximum height H2 of the curved portion 114 is between 0.05 mm and 10 mm. For instance, the thickness H1 of the base portion 112 is 0.15 mm, the diameter W of the bottom surface 110B is 3.46 mm, the radius of curvature R of the curved surface 110S is 2 mm, and the maximum height H2 of the curved portion 114 is 1 mm. In other words, the base portion 112 has an annular sidewall perpendicular to the bottom surface 110B, and the annular sidewall of the base portion 112 extends between the bottom surface 110B and the curved surface 110S. In this embodiment, the micro-structures 120 are distributed on the curved surface 110S, and the micro-structures 120 are not distributed on the sidewall of the base portion 112.

As shown in FIG. 2, the micro-structures 120 include a central circular micro-structure 122 and a plurality of annular micro-structures 124, where the annular micro-structures 124 surround the central circular micro-structure 122. The outer (outer ring) annular micro-structures among the annular micro-structures 124 may have a greater thickness (e.g., maximum thickness), while the inner (inner ring) annular micro-structures among the annular micro-structures 124 may have a smaller thickness (e.g., minimum thickness). Besides, each annular micro-structure 124 has a circular inner edge and the circular outer edge, and there is a height difference h between the circular outer edge and the circular inner edge of each annular micro-structure 124. In this embodiment, the height difference h between the circular inner edge and the circular outer edge is between −0.06 mm and 0.34 mm. When the circular outer edge of each annular micro-structure 124 is higher than the circular inner edge of the annular micro-structure 124, the height difference h between the circular outer edge and the circular inner edge is a positive value. When the circular outer edge of the annular micro-structure 124 is lower than the circular inner edge of the annular micro-structure 124, the height difference h between the circular outer edge and the circular inner edge is a negative value. As shown in FIG. 3A, the height difference h is provided between the circular outer edge and the circular inner edge of each annular micro-structure 124. When the height difference h between the circular inner edge and the circular outer edge is between −0.06 mm and 0.34 mm (that is, h=−0.06 mm, h=0 mm, and h=0.34 mm, for example), the light intensity corresponding to a center of the lens with micro-structures 100 can be effectively reduced. When the height difference h between the circular inner edge and the circular outer edge is less than −0.06 mm or greater than 0.34 mm (that is, h=−0.08 mm and h=0.36 mm, for example), the light intensity corresponding to the center of the lens with micro-structures 100 cannot be effectively reduced. In addition, a ratio (h/D) of the aforementioned height difference h to the arrangement interval D (i.e., the arrangement interval D of the annular micro-structures 124) is between −0.6 and 3.4.

Any two adjacent annular micro-structures 124 may be divided into the inner (inner ring) annular micro-structure 124 and the outer (outer ring) annular micro-structure 124. A lateral distance between the circular outer edge of the inner (inner ring) annular micro-structure 124 and the circular outer edge of the outer (outer ring) annular micro-structure 124 may be defined as the arrangement interval D. Each annular micro-structure 124 has a top width d. Taking the annular micro-structures 124 shown in FIG. 1 and FIG. 2 as an example, the height difference h between the circular outer edge and the circular inner edge of the annular micro-structure 124 is a positive value (i.e., the circular outer edge is higher than the circular inner edge of the annular micro-structure 124), the ratio (h/D) of the height difference h to the arrangement interval D is also a positive value. Further, the top width d of the annular micro-structure 124 is equal to the arrangement interval D.

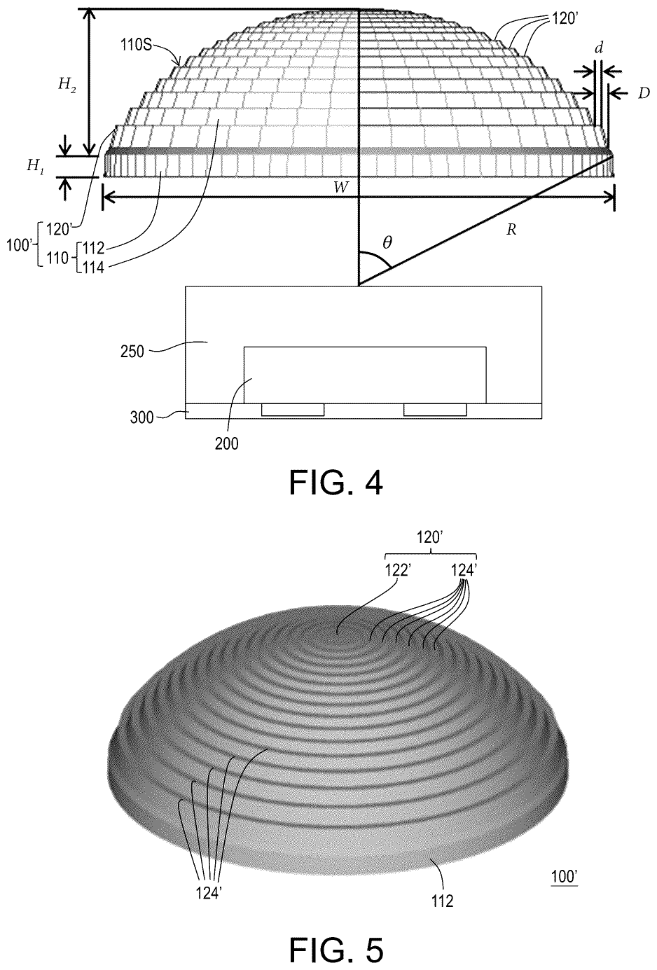

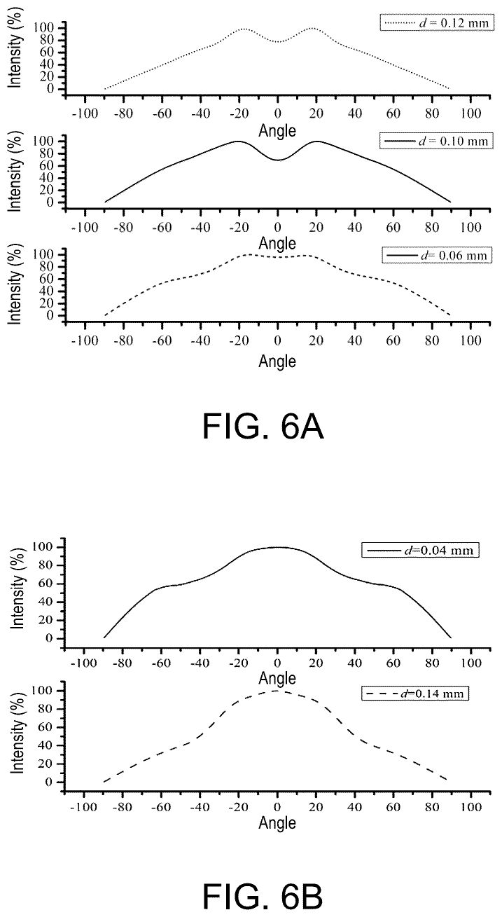

FIG. 4 is a cross-sectional schematic view of a lens with micro-structures and a light-emitting diode chip according to a second embodiment of the disclosure. FIG. 5 is a three-dimensional schematic view of the lens with micro-structures according to the second embodiment of the disclosure. FIG. 6A and FIG. 6B are schematic charts of intensity distribution of light emitted by a light-emitting diode after passing through different lenses with micro-structures according to the second embodiment of the disclosure.

With reference to FIG. 1, FIG. 2, FIG. 4, and FIG. 5, a lens with micro-structures 100′ of this embodiment is similar to the lens with micro-structures 100 of the first embodiment. In the lens with micro-structures 100′, a micro-structure 120′ includes a central circular micro-structure 122′ and a plurality of annular micro-structures 124′, where the annular micro-structures 124′ surround the central circular micro-structure 122′. The outer (outer ring) annular micro-structures among the annular micro-structures 124′ may have a greater thickness (e.g., maximum thickness), while the inner (inner ring) annular micro-structures among the annular micro-structures 124′ may have a smaller thickness (e.g., minimum thickness). Besides, each annular micro-structure 124′ has a circular inner edge and a circular outer edge, and the circular outer edge is level with the circular inner edge of each annular micro-structure 124′. In other words, there is no height difference h between the circular outer edge and circular inner edge of each annular micro-structure 124′ (i.e., the height difference h between the circular inner edge and circular outer edge of each annular micro-structure 124′ is 0). In addition, any two adjacent annular micro-structures 124′ may be divided into the inner (inner ring) annular micro-structure 124′ and the outer (outer ring) annular micro-structure 124′. A lateral distance between the circular outer edge of the inner (inner ring) annular micro-structure 124′ and the circular outer edge of the outer (outer ring) annular micro-structure 124′ may be defined as the arrangement interval D. Each annular micro-structure 124′ has a top width d. Taking the annular micro-structures 124′ shown in FIG. 4 and FIG. 5 as an example, the top width d of the annular micro-structure 124′ may range from 0.06 mm to 0.12 mm, and the ratio (d/D) of the top width d to the arrangement interval D may range from 0.6 to 1.2.

As shown in FIG. 6A, when the top width d of the annular micro-structure 124′ ranges from 0.06 mm to 0.12 mm (that is, d=0.06 mm, d=0.1 mm, and d=0.12 mm, for example), the light intensity corresponding to a center of the lens with micro-structures 100′ may be effectively reduced. When the top width d of the annular micro-structure 124′ is less than 0.06 mm or greater than 0.14 mm (that is, d=0.04 mm and d =0.14 mm, for example), the light intensity corresponding to the center of the lens with micro-structures 100′ cannot be effectively reduced.

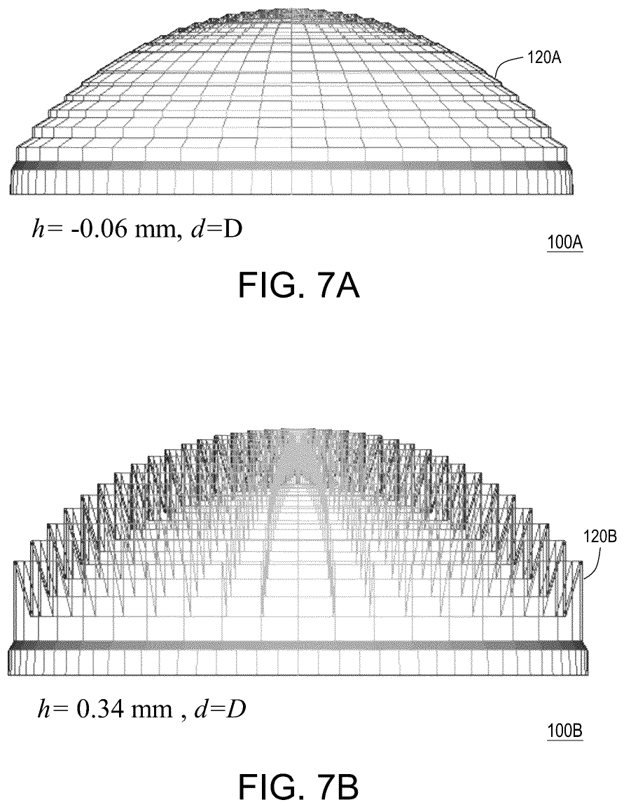

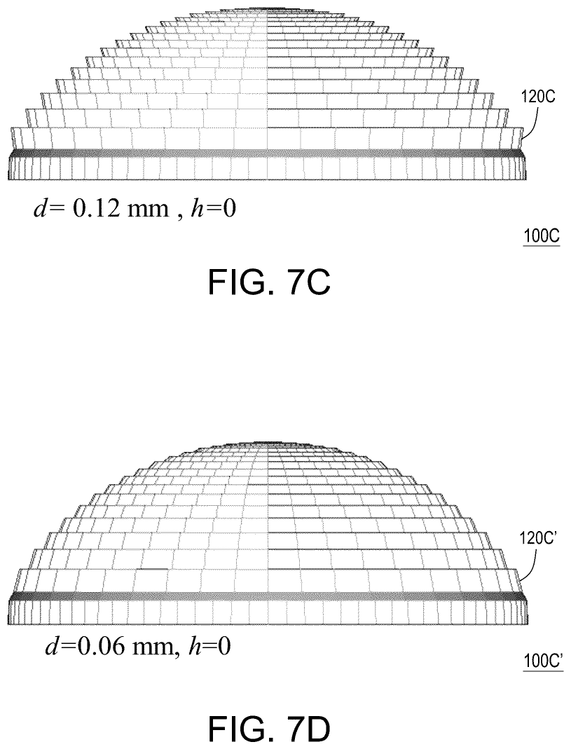

FIG. 7A to FIG. 7D are cross-sectional schematic views of lenses with micro-structures according to different embodiments of this disclosure.

With reference to FIG. 7A to FIG. 7D, in a lens with micro-structures 100 A shown in FIG. 7A, the height difference h between the circular inner edge and the circular outer edge of each annular micro-structure 120A is −0.06 mm, and the top width d of the annular micro-structure 120A is equal to the arrangement interval D. In a lens with micro-structures 100B shown in FIG. 7B, the height difference h between the circular inner edge and the circular outer edge of each annular micro-structure 120B is 0.34 mm, and the top width d of the annular micro-structure 120B is equal to the arrangement interval D. In a lens with micro-structures 100C shown in FIG. 7C, the height difference h between the circular inner edge and the circular outer edge of each annular micro-structure 120C is 0, and the top width d of the annular micro-structure 120C is 0.12 mm. In a lens with micro-structures 100C′ shown in FIG. 7D, the height difference h between the circular inner edge and the circular outer edge of each annular micro-structure 120C′ is 0, and the top width d of the annular micro-structure 120C′ is 0.06 mm.

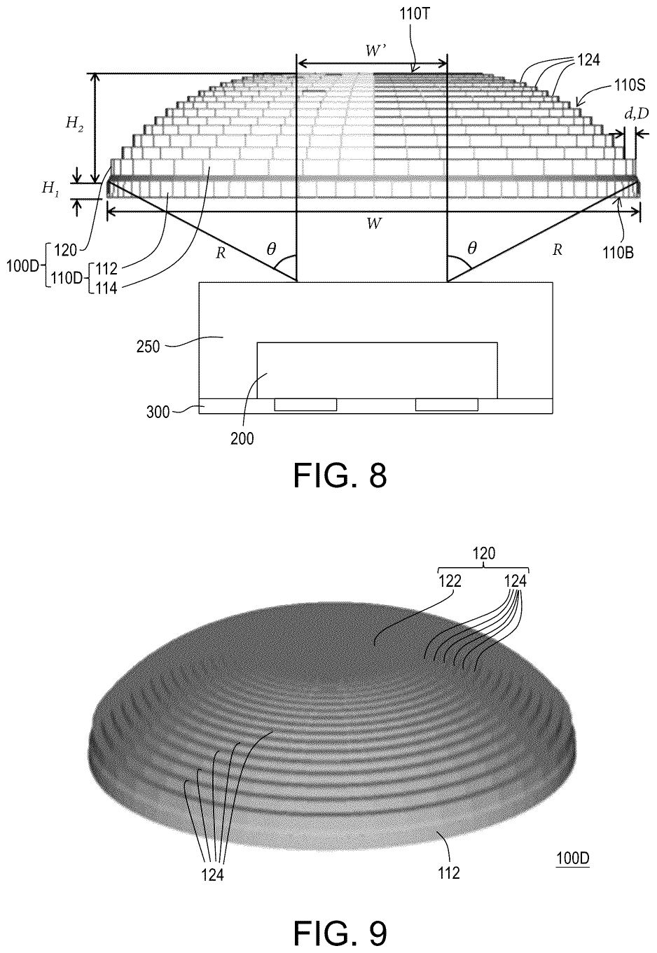

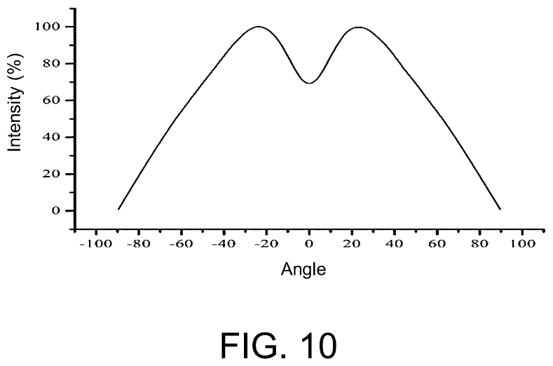

FIG. 8 is a cross-sectional schematic view of a lens with micro-structures and a light-emitting diode chip according to a third embodiment of the disclosure. FIG. 9 is a three-dimensional schematic view of the lens with micro-structures according to the third embodiment of the disclosure. FIG. 10 is a schematic chart of intensity distribution of light emitted by a light-emitting diode after passing through the lens with micro-structures according to the third embodiment of this disclosure.

With reference to FIG. 8 and FIG. 9, a lens with micro-structures 100D include a lens body 110D and a plurality of micro-structures 120. The lens body 110D has a bottom surface 110B, a top surface 110T, and a curved surface 110S, where the curved surface 110S extends between the top surface 110T and the bottom surface 110B. The micro-structures 120 are disposed on the curved surface 110S of the lens body 110D, and each of the micro-structures 120 has a circular outer edge. In view from atop of the lens body, center points of the circular outer edges of the micro-structures are located at a same position. Further, the circular outer edges are arranged at equal intervals D. Herein, the arrangement interval D may be defined as a lateral distance between the circular outer edge of each micro-structure 120 and the circular outer edge of the adjacent micro-structure 120 (e.g., the adjacent micro-structure 120 in an inner ring or in an outer ring). In this embodiment, the arrangement interval D between the micro-structures 120 may range from 0.005 mm to 0.5 mm. For instance, the arrangement interval D between the micro-structures 120 is 0.1 mm. In this embodiment, both the bottom surface 110B and the top surface 110T are flat surfaces, and in view from atop of the lens body 110D, both the bottom surface 110B and the top surface 110T have circular contours. Through the top surface 110T of the lens body 110D, the light intensity corresponding to the center of the lens with micro-structures 100D may be effectively reduced.

The lens body 110D of this embodiment includes a base portion 112 and a curved portion 114 located on the base portion 112. Herein, the base portion 112 and the curved portion 114 may be integrally formed, for example, the base portion 112 and the curved portion 114 may be made of a same optical material. In other embodiments, the base portion 112 and the curved portion 114 may be made of different optical materials (e.g., materials with different refractive indices). As can be seen from FIG. 8 and FIG. 9, a bottom surface of the base portion 112 is the bottom surface 110B of the lens body 110D, and an upper surface of the curved portion 114 is the curved surface 110S and the top surface 110T of the lens body 110D. The base portion 112 may be a circular cylinder and has a thickness H1. The bottom surface 110B of the lens body 110D may be a circular bottom surface with a diameter W. The top surface 110T of the lens body 110D may be a circular bottom surface with a diameter W′. The curved surface 110S of the curved portion 114 has a radius of curvature R and has a maximum height H2. The thickness H1 of the base portion 112 is between 0.05 mm and 5 mm, the diameter W of the bottom surface 110B is between 0.5 mm and 5 mm, the diameter W′ of the top surface 110T is between 0.1 mm and 5 mm, the radius of curvature R of the curved surface 110S is between 0.1 mm and 10 mm, and the maximum height H2 of the curved portion 114 is between 0.05 mm and 10 mm. For instance, the thickness H1 of the base portion 112 is 0.15 mm, the diameter W of the bottom surface 110B is 1.5 mm, the diameter W′ of the top surface 110T is 1.5 mm, the radius of curvature R of the curved surface 110S is 2 mm, and the maximum height H2 of the curved portion 114 is 1 mm. In other words, the base portion 112 has an annular sidewall perpendicular to the bottom surface 110B, and the annular sidewall of the base portion 112 extends between the bottom surface 110B and the curved surface 110S. In this embodiment, the micro-structures 120 are only distributed on the curved surface 110S, and the micro-structures 120 are not distributed on the sidewall of the base portion 112 nor on the top surface 110T of the lens body 110D.

As shown in FIG. 9, the micro-structures 120 include a central circular micro-structure 122 and a plurality of annular micro-structures 124, where the annular micro-structures 124 surround the central circular micro-structure 122. The outer (outer ring) annular micro-structures among the annular micro-structures 124 may have a greater thickness (e.g., maximum thickness), while the inner (inner ring) annular micro-structures among the annular micro-structures 124 may have a smaller thickness (e.g., minimum thickness). Besides, each annular micro-structure 124 has a circular inner edge and the circular outer edge, and a height difference between the circular outer edge and the circular inner edge of each annular micro-structure 124 is h. In this embodiment, the height difference h between the circular inner edge and the circular outer edge is between −0.06 mm and 0.34 mm. When the circular outer edge of each annular micro-structure 124 is higher than the circular inner edge of the annular micro-structure 124, the height difference h between the circular outer edge and the circular inner edge is a positive value. When the circular outer edge of the annular micro-structure 124 is lower than the circular inner edge of the annular micro-structure 124, the height difference h between the circular outer edge and the circular inner edge is a negative value. In addition, a ratio (h/D) of the aforementioned height difference h to the arrangement interval D (i.e., the arrangement interval D of the annular micro-structures 124) is between −0.6 and 3.4.

Any two adjacent annular micro-structures 124 may be divided into the inner (inner ring) annular micro-structure 124 and the outer (outer ring) annular micro-structure 124. A lateral distance between the circular outer edge of the inner (inner ring) annular micro-structure 124 and the circular outer edge of the outer (outer ring) annular micro-structure 124 may be defined as the arrangement interval D. Each annular micro-structure 124 has a top width d. Taking the annular micro-structures 124 shown in FIG. 8 and FIG. 9 as an example, the height difference h between the circular outer edge and the circular inner edge of the annular micro-structure 124 is 0 (i.e., the circular outer edge is level with the circular inner edge of the annular micro-structure 124), the ratio (h/D) of the height difference h to the arrangement interval D is also 0. Further, the top width d of the annular micro-structure 124 is equal to the arrangement interval D.

With reference to FIG. 10, through the top surface 110T of the lens body 110D and the design of the annular micro-structures 124, the light intensity corresponding to the center of the lens with micro-structures 100D may be effectively reduced.

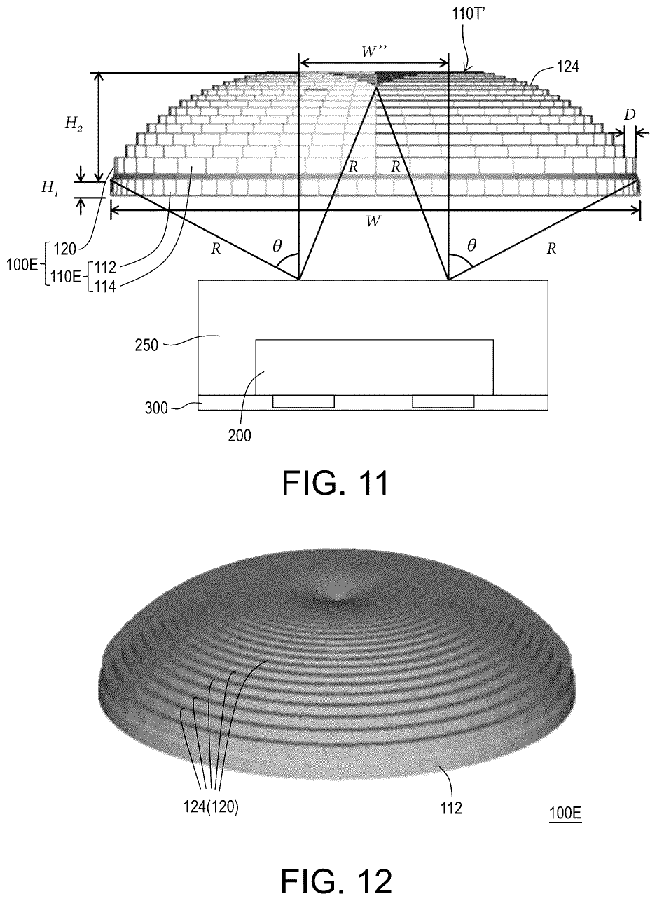

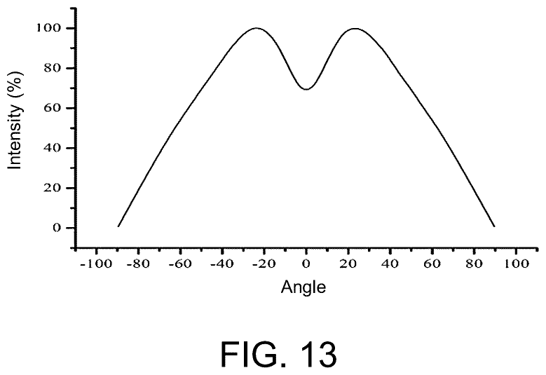

FIG. 11 is a cross-sectional schematic view of a lens with micro-structures and a light-emitting diode chip according to a fourth embodiment of the disclosure. FIG. 12 is a three-dimensional schematic view of the lens with micro-structures according to the fourth embodiment of the disclosure. FIG. 13 is a schematic chart of intensity distribution of light emitted by a light-emitting diode after passing through the lens with micro-structures according to the fourth embodiment of this disclosure.

With reference to FIG. 8, FIG. 9, FIG. 11, and FIG. 12, a lens with micro-structures 100E of this embodiment is similar to the lens with micro-structures 100D of the third embodiment. A top surface 110T′ of the lens with micro-structures 100E is a recessed region and has the same radius of curvature R as the curved portion. The micro-structures 120 are not distributed on the sidewall of the base portion 112 nor on the recessed region 110T′ of the top surface of the lens body 110E.

With reference to FIG. 13, through the design of the annular micro-structures 124 and the recessed region of the lens body 110E, the light intensity corresponding to the center of the lens with micro-structures 100D may be effectively reduced.

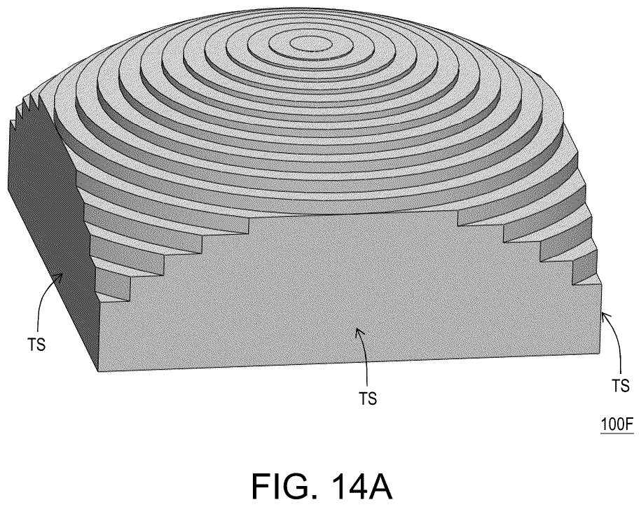

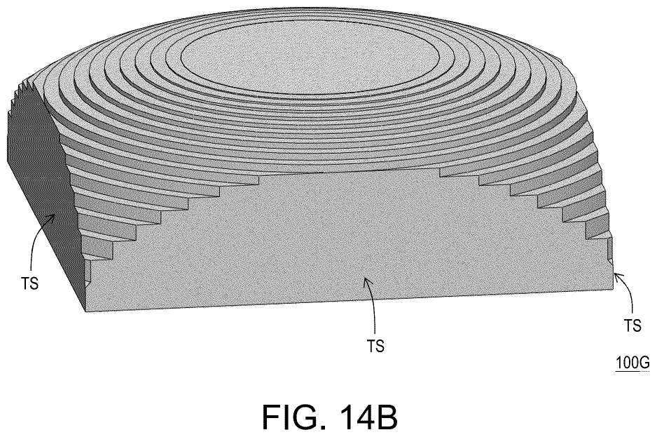

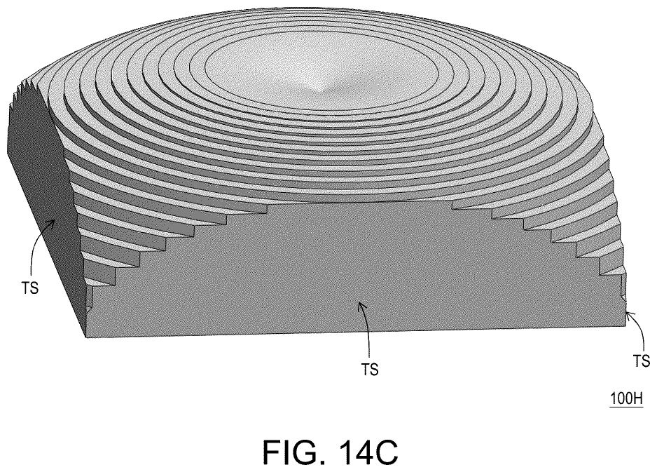

FIG. 14A to FIG. 14C are three-dimensional schematic views of lenses with micro-structures according to other embodiments of this disclosure. Lenses with micro-structures 100F, 100G, and 100H of this embodiment are similar to the lenses with micro-structures 100′, 100D, and 100E in the aforementioned embodiments. Each of the lenses with micro-structures 100F, 100G, and 100H has at least one trimming side surface TS, so that the lenses with micro-structures 100F, 100G, and 100H may be designed with the required configuration according to needs.

In the embodiments of the disclosure, the annular micro-structures on the lens body are arranged at equal intervals in the horizontal direction, so that the light intensity corresponding to the center of the lens with micro-structures is effectively reduced, and that the surface light source using this lens with micro-structures may exhibit improved uniformity.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A lens with micro-structures, comprising
a lens body having a bottom surface and a curved surface; and
a plurality of micro-structures disposed on the curved surface of the lens body, wherein each of the micro-structures has a circular outer edge, in view from atop of the lens body, center points of the circular outer edges of the micro-structures are located at a same position, and the circular outer edges are arranged at equal intervals.

2. The lens with micro-structures according to claim 1, wherein the micro-structures comprise:
a central circular micro-structure; and
a plurality of annular micro-structures surrounding the central circular micro-structure, wherein thicknesses of the outer annular micro-structures among the micro-structures is greater than thicknesses of the inner annular micro-structures among the annular micro-structures.

3. The lens with micro-structures according to claim 1, wherein each of the micro-structures has a circular inner edge and the circular outer edge, and in each of the micro-structures, the circular outer edge is higher than the circular inner edge.

4. The lens with micro-structures according to claim 1, wherein each of the micro-structures has a circular inner edge and the circular outer edge, and in each of the micro-structures, the circular outer edge is lower than the circular inner edge.

5. The lens with micro-structures according to claim 1, wherein each of the micro-structures has a circular inner edge and the circular outer edge, and in each of the micro-structures, the circular outer edge is level with the circular inner edge.

6. The lens with micro-structures according to claim 1, wherein each of the micro-structures has a circular inner edge and the circular outer edge, and in each of the micro-structures, a height difference between the circular outer edge and the circular inner edge is between −0.06 mm and 0.34 mm.

7. The lens with micro-structures according to claim 1, wherein each of the micro-structures has a circular inner edge and the circular outer edge, a height difference between the circular outer edge and the circular inner edge is h, an arrangement interval of the circular outer edges is D, and a ratio (h/D) is between −0.6 and 3.4.

8. A lens with micro-structures, comprising
a lens body having a bottom surface, a top surface, and a curved surface, wherein the curved surface extends between the top surface and the base surface; and
a plurality of micro-structures disposed on the curved surface of the lens body, wherein each of the micro-structures has a circular outer edge, in view from atop of the lens body, center points of the circular outer edges of the micro-structures are located at a same position, and the circular outer edges are arranged at equal intervals.

9. The lens with micro-structures according to claim 8, wherein the bottom surface and the top surface are planar, and in view from atop of the lens body, the base surface and the top surface have a circular contour.

10. The lens with micro-structures according to claim 8, wherein the micro-structures comprise a plurality of first annular micro-structures surrounding the top surface, wherein thicknesses of the outer annular micro-structures among the first micro-structures is greater than thicknesses of the inner annular micro-structures among the first annular micro-structures.

11. The lens with micro-structures according to claim 8, wherein each of the micro-structures has a circular inner edge and the circular outer edge, and in each of the micro-structures, the circular outer edge is higher than the circular inner edge.

12. The lens with micro-structures according to claim 8, wherein each of the micro-structures has a circular inner edge and the circular outer edge, and in each of the micro-structures, the circular outer edge is lower than the circular inner edge.

13. The lens with micro-structures according to claim 8, wherein each of the micro-structures has a circular inner edge and the circular outer edge, and in each of the micro-structures, the circular outer edge is level with the circular inner edge.

14. The lens with micro-structures according to claim 8, wherein each of the micro-structures has a circular inner edge and the circular outer edge, and in each of the micro-structures, a height difference between the circular outer edge and the circular inner edge is between −0.06 mm and 0.34 mm.

15. The lens with micro-structures according to claim 8, wherein each of the micro-structures has a circular inner edge and the circular outer edge, a height difference between the circular outer edge and the circular inner edge is h, an arrangement interval of the circular outer edges is D, and a ratio (h/D) is between −0.6 and 3.4.

16. The lens with micro-structures according to claim 8, wherein the top surface is a recessed region.
